(19) United States
(12) Patent Application Publication
(10) Pub. No.: US 2009/0087285 A1
(43) Pub. Date: Apr. 2, 2009

(54) SUBSTRATE PROCESSING APPARATUS

(76) Inventor: Ichiro Mitsuyoshi, Kyoto (JP)

Correspondence Address: OSTROLENK FABER GERB & SOFFEN, 1180 AVENUE OF THE AMERICAS, NEW YORK, NY, 100368403, US

(21) Appl. No.: 12/209,242

(22) Filed: Sep. 12, 2008

(30) Foreign Application Priority Data
Sep. 27, 2007 (JP) JP2007-250855

(51) Int. Cl. H01L 21/677

(52) U.S. Cl. 414/217

(57) ABSTRACT

An FOUP transport robot transports an FOUP, which stores a plurality of substrates, between a loading port and an FOUP placement stage. An indexer robot transfers substrates (unprocessed substrates) stored in the FOUP placed on the FOUP placement stage, to a cleaning part through a substrate transfer part; or receives and stores substrates (processed substrates) subjected to scrub cleaning in the cleaning part, into the FOUP through the substrate transfer part. A plurality of FOUP placement stages are provided around the indexer robot, so that the indexer robot does not have to move in a horizontal direction at the time of transport.

### BACKGROUND OF THE INVENTION

1. Field of the Invention

The present invention relates to a substrate processing apparatus that processes a substrate such as a semiconductor substrate, a glass substrate for liquid crystal displays or for photomasks, or an optical disk substrate.

2. Description of the Background Art

Products such as semiconductors and liquid crystal displays are fabricated by processing a substrate as described above in a series of processing steps including cleaning, resist coating, exposure, development, etching, formation of an interlayer insulation film, heat treatment, dicing, and the like. A substrate processing apparatus performing such processing steps is configured by incorporating processing units that perform processing steps and a transport robot that transports substrates to each of the processing units.

For instance, what is called a coater-and-developer is widely used, which is an apparatus that incorporates therein a coating unit applying a resist coating to a substrate; a development unit performing development of a substrate; and a transport robot transporting a substrate between the coating unit and the development unit.

One example of such a substrate processing apparatus is given for example in Japanese Patent Application Laid-Open No. 2005-93653, which discloses a coater-and-developer that includes a plurality of cells, which are juxtaposed to one another and each of which includes a single transport robot and a plurality of processing units to and from which substrates are transported; and a substrate transfer part provided between cells, and that performs substrate transfer between the transport robots of adjacent cells.

While the apparatus disclosed in Japanese Patent Application Laid-Open No. 2005-93653 performs resist-coating and development of a substrate, the same configuration such as to connect a plurality of cells through a substrate transfer part is also considered applicable to apparatuses that perform other kinds of processing, e.g., a cleaning apparatus that cleans substrates with a brush or the like. For example, such a cleaning apparatus, as illustrated in plan view in FIG. 8, may be configured such that an indexer cell 910 accumulating therein unprocessed and processed substrates and a cleaning cell 920 including cleaning units 94 for cleaning are connected through a substrate transfer part 93. The indexer cell 910 and the cleaning cell 920 are provided with transport robots 92 and 95, respectively, which are designed for exclusive use for each cell.

However, as compared to what is called a coater-and-developer as disclosed in Japanese Patent Application Laid-Open No. 2005-93653, the cleaning apparatus has a shorter cycle time so that an unprocessed substrate transferred from the indexer cell to the cleaning cell will return to the indexer cell in a very short period of time after completion of the cleaning process. Thus in many cases, the overall throughput of the cleaning apparatus is determined by the processing time in the indexer cell, i.e., the indexer cell is rate-determining.

Thus, to improve the throughput, it is necessary to increase the processing speed of the indexer cell; more specifically, it is contemplated to increase the operating speed of a transport mechanism in the indexer cell. Increasing only the operating speed of the transport mechanism, however, can cause another problem that stable substrate transport is difficult at excessively high speeds.

### SUMMARY OF THE INVENTION

The invention is intended to provide a single-wafer-processing-type substrate processing apparatus that processes one substrate at a time, the substrate being stored in a holder storing a plurality of substrates.

According to an aspect of the invention, the substrate processing apparatus includes: a plurality of first placement parts placing the holder for transfer of the holder to and from outside the apparatus; a plurality of second placement parts arranged on the circumference of a circle with center on a given vertical axis; a holder transporter transporting the holder placed on any one of the plurality of first placement parts to any one of the plurality of second placement parts; and a substrate transfer part fixedly provided in such a position that a pivot extending vertically to said substrate transfer part agrees with the given vertical axis, said substrate transfer part, without moving in a horizontal direction, taking a substrate out of the holder placed on any one of the plurality of second placement parts to transfer the substrate to a given substrate transfer position or storing a substrate received from the substrate transfer position into the holder.

In this configuration, the holder is placed on each of the plurality of second placement parts around the substrate transfer part; and the substrate transfer part, without moving in a horizontal direction, takes a substrate out of the holder to transfer the substrate to the substrate transfer position or stores a substrate received from the substrate transfer position into the holder. This reduces the time required for substrate transport. Besides, the provision of the plurality of second placement parts avoids interruption of substrate transport, thus allowing efficient substrate transport without any waste of time.

Preferably, each of the plurality of second placement parts and the substrate transfer position are so located as to form an angle of 90 degrees as viewed from the substrate transfer part.

In such a configuration, the substrate transfer part provides rapid substrate transport between the holder placed on each of the plurality of second placement parts and the substrate transfer position.

Preferably, the plurality of second placement parts include two second placement parts.

Preferably, an average level at which an access is made to the holder placed on each of said plurality of second placement parts is approximately the same as an average level at which an access is made to the substrate transfer position.

This configuration shortens an average distance of substrate transport between the holder and the substrate transfer position, thus reducing the time required for substrate transport.

Preferably, the substrate processing apparatus further includes a cleaning part cleaning a substrate; and a transporter transporting a substrate between the cleaning part and the substrate transfer position.

The invention is also intended to provide a substrate transport method for transporting a substrate in a substrate processing apparatus that includes a single-wafer-processing-type substrate processing unit that processes one substrate at a time.

It is thus an object of the invention to provide a substrate processing apparatus that reduces the time required for substrate transport in the entire apparatus.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view of a substrate processing apparatus according to a preferred embodiment of the invention;

FIGS. 2 and 3 are side sectional views of the substrate processing apparatus according to the preferred embodiment of the invention;

FIG. 4A and 4B are perspective views of the structures of an FOUP and an opener, respectively;

FIG. 5 shows the procedure for processing in a substrate processing apparatus;

FIG. 6 is a plan view of a substrate processing apparatus according to a modification of the invention;

FIGS. 7A and 7B are, respectively, a plan view and a side sectional view of the substrate processing apparatus according to a modification of the invention; and

FIG. 8 illustrates a configuration of a conventional substrate processing apparatus.

### DESCRIPTION OF THE PREFERRED EMBODIMENTS

Now, preferred embodiments of the invention are described in detail with reference to the drawings.

### <1. Configuration of Substrate Processing Apparatus>

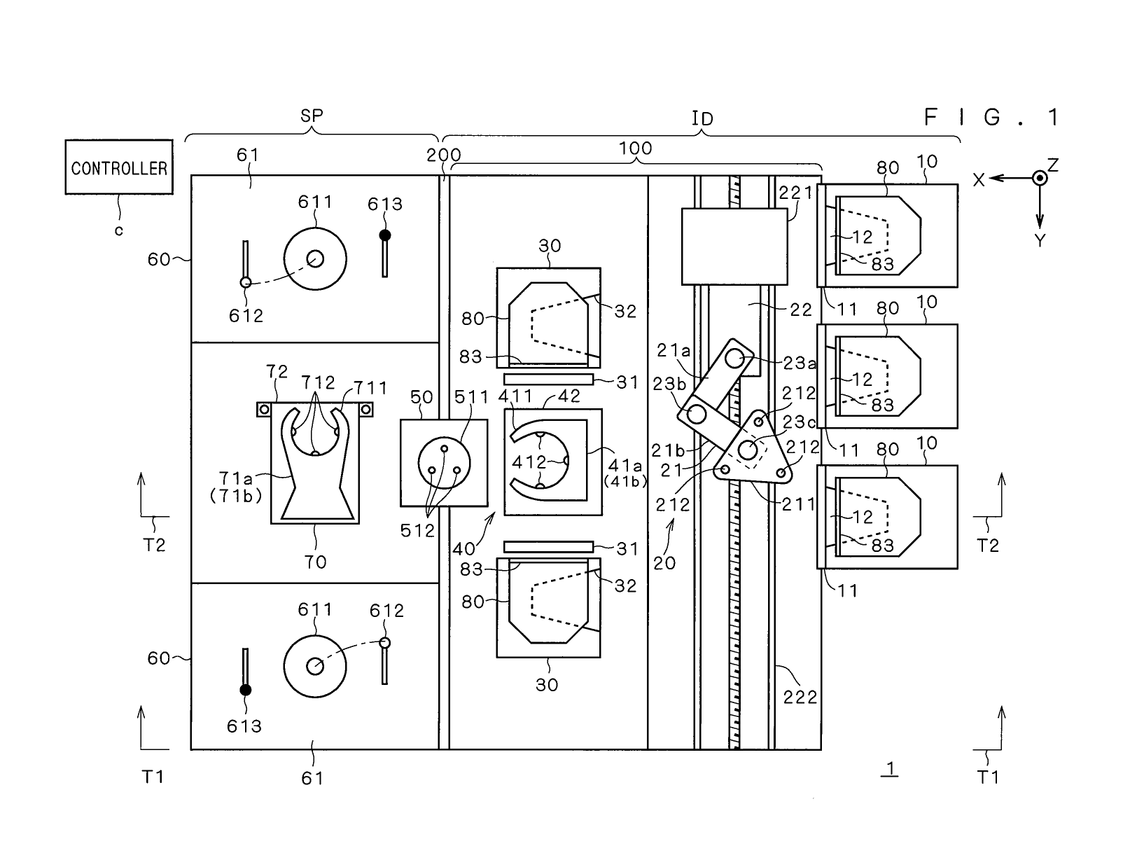

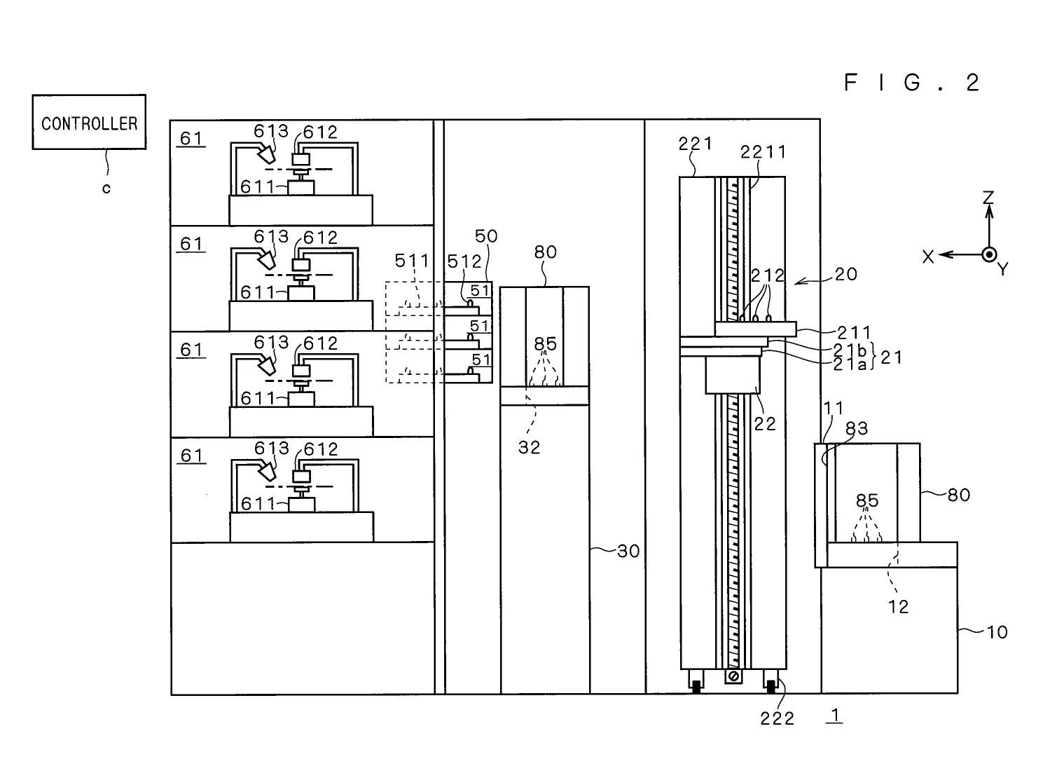

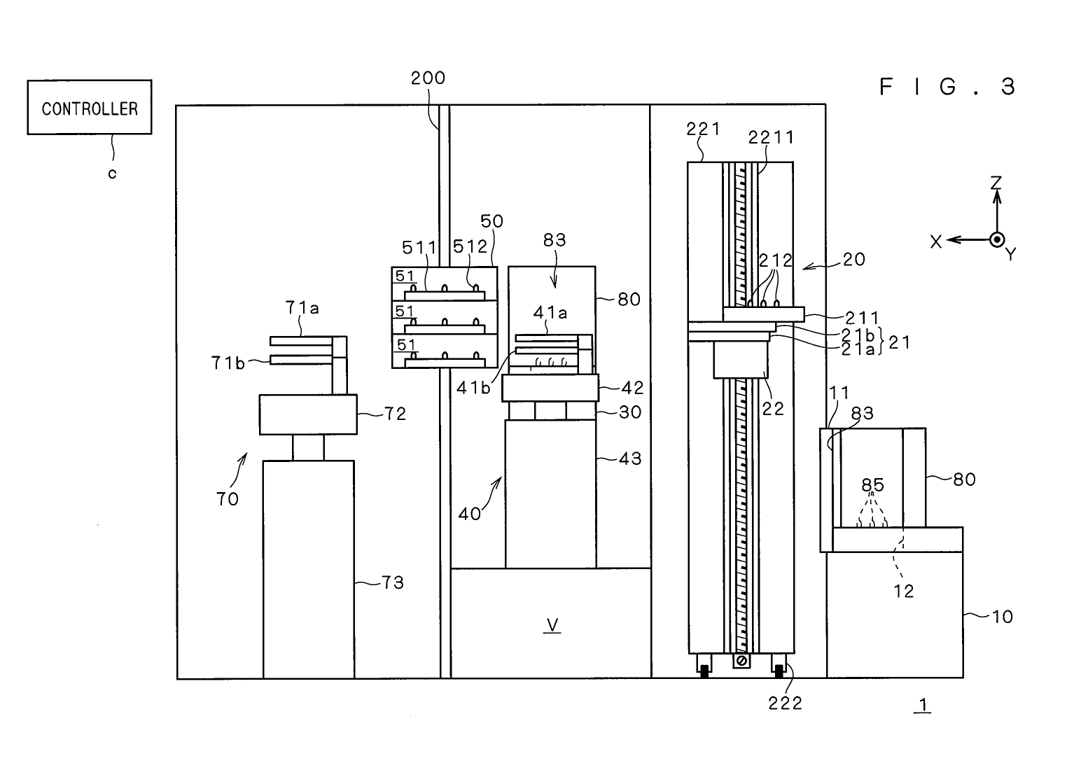

A configuration of a substrate processing apparatus according to a preferred embodiment of the invention is described with reference to FIGS. 1 to 3. FIG. 1 is a plan view of a substrate processing apparatus 1; FIG. 2 is a side sectional view of the substrate processing apparatus 1 as viewed in the direction of the arrow T1 in FIG. 1; and FIG. 3 is a side sectional view of the substrate processing apparatus 1 as viewed in the direction of the arrow T2 in FIG. 1. In order to clarify directional relationship of FIGS. 1 to 3 as necessary, FIGS. 1 to 3 additionally show an XYZ rectangular coordinate system where the Z-axis direction shall be a vertical direction and the XY plane shall be a horizontal plane.

The substrate processing apparatus 1 is a single-wafer-processing-type apparatus that scrubs and cleans a set of substrates (lots) stored in a front-opening unified pod (FOUP) 80, one substrate at a time. The substrate processing apparatus 1 includes an indexer cell ID and a cleaning cell SP which are juxtaposed to each other. A partition wall 200 for cutting off the atmosphere is provided between the indexer cell ID and the cleaning cell SP, and a substrate transfer part 50 is provided passing through part of the partition wall 200.

The substrate processing apparatus 1 further includes a controller C that controls each of the cells ID and SP. A functional unit in each of the cells ID and SP (e.g., drive mechanisms of an FOUP transfer robot 20 and an indexer robot 40 which will be described later) are in electrical connection with the controller C.

### <1-1. FOUP 80>

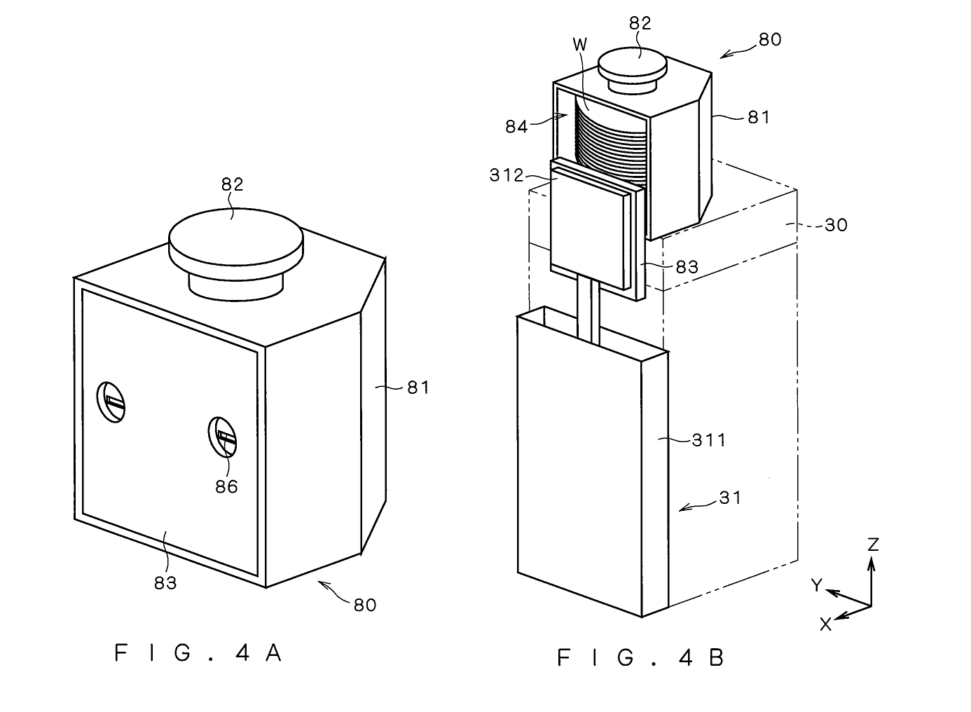

Prior to the description of each of the cells ID and SP, the FOUP 80 is described with reference to FIGS. 4A and 4B. FIG. 4A is a perspective view of the structure of the FOUP 80, and FIG. 4B is a perspective view of the structure of an opener 31 that removes a lid (a front lid 83) attached to the FOUP 80. For convenience in describing the drawing, the X, Y, and Z axes are defined in FIG. 4B.

The FOUP 80 stores a plurality of (e.g., 25 or 13) substrates W in its own casing 81. Inside the FOUP 80, the substrates W are stored with their major surfaces lying along the horizontal direction.

The casing 81 has the front lid 83 on one side. The front lid 83 has a locking mechanism (the detail of which is not shown) that provides a lock for the casing 81. When the locking mechanism functions with the front lid 83 attached to the casing 81 (i.e., when an attachment and detachment mechanism of the opener 31, which will be described later, is actuated by being fitted into lock holes 86), the front lid 83 of the casing 81 is locked or unlocked. The casing 81 with its front lid 83 locked provides an enclosed space therein, so that the inside of the FOUP 80 is maintained at a high degree of cleanliness, irrespective of external cleanliness.

The front lid 83 is removed by the opener 31 with the FOUP 80 placed on an FOUP placement stage 30 (cf. FIG. 1), which will be described later, as illustrated in FIG. 4B. The opener 31 has an opening at the top and includes a housing 311 fixed to a machine frame or the like; and an attachment and detachment hand 312 that is movable back and forth in the X-axis direction and movable up and down in the vertical direction with respect to the housing 311. The attachment and detachment hand 312 is provided with an attachment and detachment mechanism (not shown) that activates or inactivates the locking mechanism of the front lid 83 when fitted into the lock holes 86. This attachment and detachment mechanism also holds the front lid 83 removed from the casing 81. When the attachment and detachment hand 312 releases the locking mechanism of the front lid 83 and holds and moves downward the removed front lid 83, an opening 84 is formed on one side of the FOUP 80. Through this opening 84, the substrates W are transported into and out of the apparatus.

The casing 81 also has a flange 82 on the top. An external transporter, such as an overhead hoist transport (OHT) or an automatic guided vehicle (AVG), for example, holds this flange 82 from both sides, thereby suspending and holding the FOUP 80.

The casing 81 still also has three holes 85 in the bottom (see, for example, FIG. 2). The locations and sizes of the holes 85 are so determined that the holes 85 fit into projections 212 (see, for example, FIG. 2) formed on a transport arm 21 of the FOUP transfer robot 20 which will be described later. By fitting the projections 212 formed at the ends of the transport arm 21 into these holes 85, the FOUP transfer robot 20, which will be described later, lifts the FOUP 80 from the underside, thus providing stable transport.

### <1-2. Indexer Cell ID>

The indexer cell ID is a cell that delivers an unprocessed substrate received from outside the substrate processing apparatus 1 to the cleaning cell SP and that transports a processed substrate received from the cleaning cell SP to outside the substrate processing apparatus 1.

The indexer cell ID includes a plurality of (three, in the present preferred embodiment) loading ports 10 and a loader-and-unloader part 100 located in a space between the loading ports 10 and the cleaning cell SP. The loader-and-unloader part 100 includes the FOUP transfer robot 20, a plurality of (two, in the present preferred embodiment) FOUP placement stages 30, and the indexer robot 40.

### [Loading Ports 10]

Each of the plurality of (three, in the present preferred embodiment) loading ports 10 is a placement stage that places an FOUP 80 transferred from a transporter (such as an OHT or an AVG) outside the substrate processing apparatus 1 or from an operator of the substrate processing apparatus 1. Each of the loading ports 10 has a shutter 11 on one side on the side of the loader-and-unloader part 100. Opening the shutter 11 provides an opening that provides communications between the loading ports 10 and the loader-and-unloader part 100.

Each of the loading ports 10 has on the upper surface an open recess 12 that opens into a direction accessible from the FOUP transfer robot 20. The area of the open recess 12 is larger than that of a holding part 211 of the FOUP transfer robot 20 which will be described later, and is smaller than the bottom surface area of the FOUP 80. The depth of the open recess 12 is greater than the thickness of the holding part 211. By putting the holding part 211 formed at the end portion of the transport arm 21 into this open recess 12, the FOUP transfer robot 20, which will be described later, can fit the projections 212 into the holes 85 formed in the underside of the FOUP 80 placed on the loading port 10.

### [FOUP Transport Robot 20]

The FOUP transfer robot 20 is a transporter that transports FOUPs 80 between the loading ports 10 and the FOUP placement stages 30. To be more specific, an FOUP 80 (an FOUP that stores unprocessed substrates) placed on a given loading port 10 is brought into the loader-and-unloader part 100 through the opening formed by opening the shutter 11, and then is placed on a given FOUP placement stage 30. Or, an FOUP 80 placed on a given FOUP placement stage 30 is transported out of the loader-and-unloader part 100 and is then transferred to a given loading port 10.

The structure of the FOUP transfer robot 20 is now described in more detail. The FOUP transfer robot 20 includes the transport arm 21; and an elevating stage 22 mounting the transport arm 21.

The elevating stage 22 is mounted to a column 221 formed with a guide rail 2211 extending in the vertical (Z-axis) direction, so that it is movable up and down along the guide rail 2211. The column 221 is slidably mounted along a guide rail 222 extending in the horizontal (Y-axis) direction. The elevating stage 22 can thus move in the Y- and Z-axis directions.

A first portion 21a of the transport arm 21 is mounted to the elevating stage 22 through a rotary shaft 23a along the vertical (Z-axis) direction. The rotary shaft 23a is connected to a rotary motor (not shown). This allows the first portion 21a to turn on the rotary shaft 23a.

A second portion 21b of the transport arm 21 is mounted to the end portion of the first portion 21a through a rotary shaft 23b along the vertical (Z-axis) direction. The rotary shaft 23b is connected to a rotary motor (not shown). This allows the second portion 21b to turn on the rotary shaft 23b.

The holding part 211 in a generally triangular shape as viewed in plan view is mounted to the end portion of the transport arm 21 through a rotary shaft 23c along the vertical (Z-axis) direction. The rotary shaft 23c is connected to a rotary motor (not shown). This allows the holding part 211 to turn on the rotary shaft 23c.

The holding part 211 has the projections 212 formed in the vicinity of the vertices on its upper surface side. By fitting these projections 212 into the holes 85 formed in the bottom of an FOUP 80, the FOUP transfer robot 20 can stably support one FOUP 80 from the underside.

The FOUP transfer robot 20 with such a structure allows its transport arm 21 to move up and down, to move horizontally along the Y-axis direction, to pivot in a horizontal plane, and to move back and forth in the radial direction of the pivot. In other words, the FOUP transfer robot 20 allows the transport arm 21 to have access to a given loading port 10 and to a given FOUP placement stage 30. That is, transport of FOUPs 80 is provided between the loading ports 10 and the FOUP placement stages 30.

To be described later, the above-described opener 31 (see FIG. 4B for the detailed structure) is provided between each of the FOUP placement stages 30 and the indexer robot 40. When transferring a transported FOUP 80 on a given FOUP placement stage 30, the FOUP transfer robot 20 turns the FOUP 80 on the vertical axis (Z-axis) to change the orientation of the FOUP 80 as appropriate so that the front lid 83 of the FOUP 80 faces the opener 31. To be more specific, the FOUP transfer robot 20 places a holding FOUP 80 on a given FOUP placement stage 30 after rotating the holding part 211 that holds the FOUP 80 on the rotary shaft 23c at a given angle to thereby reorient the FOUP 80 in a proper direction. The reorientation of the FOUP 80 may be done by the FOUP transfer robot 20 in the way described above, or may be done by a mechanism that is provided on each of the FOUP placement stages 30 to turn the FOUP 80 placed thereon.

### [FOUP Placement Stages 30]

Each of the plurality of (two, in the present preferred embodiment) FOUP placement stages 30 is a placement stage that places an FOUP 80 received from the FOUP transfer robot 20.

Each of the two FOUP placement stages 30 is so located that the FOUP placement stage 30 and the substrate transfer part 50 form an angle of 90 degrees as viewed from the indexer robot 40. In particular according to the present preferred embodiment, each of the FOUP placement stages 30 is located at the same level. In other words, the two FOUP placement stages 30 are located so as to face each other with the indexer robot 40 in between, on the circumference of a circle with center on a pivot along the vertical (Z-axis) direction of an arm stage 42 which will be described later.

Each of the FOUP placement stages 30 is located so that an FOUP 80 placed on the FOUP placement stage 30 and the substrate transfer part 50, which will be described later, are approximately at the same level. To be more specific, each of the FOUP placement stages 30 is located so that an average level at which an access is made to tiers of PASSs 51 (e.g., a level at which an access is made to a middle tier of PASSs 51) is approximately equal to an average level at which an access is made to each substrate support shelf in an FOUP 80 placed on the FOUP placement stage 30 (e.g., a level at which an access is made to a middle tier of substrate support shelves in the FOUP 80).

The above-described opener 31 is provided between each of the FOUP placement stages 30 and the indexer robot 40. An FOUP 80, as described above, is placed by the FOUP transfer robot 20 on a given FOUP placement stage 30 so that its front lid 83 faces the opener 31. The opener 31 can thus remove the front lid 83 of the FOUP 80. Removal of the front lid 83 by the opener 31 provides the opening 84 (cf. FIG. 4B), through which the indexer robot 40 takes a substrate W (unprocessed substrate) out of the FOUP 80, or stores a substrate W (a processed substrate) into the FOUP 80.

Each of the FOUP placement stages 30, like the loading ports 10, has in the upper surface an open recess 32 that opens into a direction accessible from the FOUP transfer robot 20. The open recesses 32 are similar in dimensions to the open recesses 12. By putting the holding part 211 formed at the end portion of the transport arm 21 into this open recess 32, the FOUP transfer robot 20 can fit the projections 212 into the holes 85 formed in the underside of an FOUP 80 placed on the FOUP placement stage 30.

### [Indexer Robot 40]

The indexer robot 40 is a transporter that transports a substrate W between an FOUP 80 placed on a given FOUP placement stage 30 and a given substrate transfer position (the substrate transfer part 50). To be more specific, through the opening 84 formed by removing the front lid 83 by the opener 31, a substrate W (unprocessed substrate) stored in the FOUP 80 placed on a given FOUP placement stage 30 is taken out and transferred to a given PASS 51 in the substrate transfer part 50. Or, a substrate W (processed substrate) placed on a given PASS 51 is taken out and stored in an FOUP 80 placed on a given FOUP placement stage 30.

The structure of the indexer robot 40 is now described in more detail. The indexer robot 40 includes two transport arms 41a and 41b; the arm stage 42 mounting the transport arms 41a and 41b; and a fixed stage 43 mounting the arm stage 42.

The fixed stage 43 is fixed to the base of the indexer cell ID. The fixed stage 43 includes a built-in motor (not shown) that drives the arm stage 42 to pivot on an axis along the vertical (Z-axis) direction; and another built-in motor (not shown) that moves the arm stage 42 up and down along the vertical direction. The arm stage 42 can thus make a turn and moves up and down.

The two transport arms 41a and 41b are provided one above the other with given pitches on the arm stage 42, as shown in FIG. 3. Each of the transport arms 41a and 41b includes, as shown in FIG. 1, a C-shaped frame 411 in plan view at the end portion and supports the edge of a substrate W from below, using a plurality of (three, in the present preferred embodiment) pins 412 that protrude inward from inside the frame 411. Each of the transport arms 41a and 41b can thus hold a single substrate W. The arm stage 42 also includes a built-in slide drive mechanism (not shown) that moves the transport arms 41a and 41b back and forth in the horizontal direction (in the radial direction of the pivot of the arm stage 42). This mechanism allows the transport arms 41a and 41 to move back and forth.

The indexer robot 40 with such a structure allows its transport arms 41a and 41b to move up and down, to pivot in a horizontal plane, and to move back and forth in the radial direction of the pivot. In other words, the indexer robot 40 pivots the transport arms 41a and 41b so that the transport arms 41a and 41b face a given FOUP placement stage 30, and further at that position, moves the transport arms 41a and 41b up and down and back and forth, thereby allowing the transport arms 41a and 41b to have access to a given tier in an FOUP 80 placed on the FOUP placement stage 30. Also, the indexer robot 40 pivots the transport arms 41a and 41b so that the transport arms 41a and 41b face the substrate transfer part 50, and further at that position, moves the transport arms 41a and 41b up and down and back and forth, thereby allowing the transport arms 41a and 41b to have access to a given tier of PASSs 51. In other words, the indexer robot 40 allows the transport arms 41a and 41b to have access to a given FOUP 80 and to a given PASS 51 without moving in the X and Y directions (i.e., without moving in the horizontal direction).

When the indexer robot 40 transports substrates W (unprocessed substrates) stored in an FOUP 80 placed on a given FOUP placement stage 30, each of the two transport arms 41a and 41b simultaneously takes out one unprocessed substrate W stored in the FOUP 80 at a time and then simultaneously places that substrate W on a given PASS 51. In other words, both of the arms simultaneously take a total of two substrates W out of the FOUP 80 and place them on given two PASSs 51. When storing substrates W (processed substrates) placed on an PASS 51 into an FOUP 80 placed on a given FOUP placement stage 30, each of the two transport arms 41a and 41b simultaneously takes out one substrate W (processed substrate) placed on the PASS 51 and then stores that substrate into the FOUP 80. In other words, both of the arms simultaneously takes a total of two substrates W out of the substrate transfer part 50 and store them in the FOUP 80.

### <1-3. Substrate Transfer Part 50>

The substrate transfer part 50 is provided, passing through part of the partition wall 200 between the indexer cell ID and the cleaning cell SP, to transfer substrates W between both of the cells.

The substrate transfer part 50 includes three substrate placement parts (PASSs) 51 stacked one above another in layers. Each of the PASSs 51 includes a plurality of (e.g., three) fixed support pins 512 provided upright on a flat plate 511.

The indexer robot 40 and a center robot 70 which will be described later cause each of their transport arms 41a and 41b (71a and 71b) to access any one of the three tiers of PASSs 51 to thereby take out a substrate W placed on the plate 511 in that PASS 51. Or, they transfer substrates W held by the transport arms 41a and 41b onto given plates 511.

Each of the PASSs 51 is provided with an optical sensor (not shown) that detects the presence or absence of a substrate W placed on the plate 511. Based on a detection signal from each optical sensor, the controller C determines whether or not the indexer robot 40 and the center robot 70 which will be described later will transfer a substrate W to or from each of the PASSs 51.

### <1-4. Cleaning Cell SP>

The cleaning cell SP is a cell that scrubs and cleans unprocessed substrates received from outside the substrate processing apparatus 1.

The cleaning cell SP includes two cleaning parts 60 and the center robot 70. The two cleaning parts 60 are arranged to face each other with the center robot 70 in between.

### [Cleaning Parts 60]

Each of the cleaning parts 60 includes four cleaning units 61 having the same structure and stacked one above another in layers. The cleaning units 61 are processing units that scrubs and cleans the surfaces (the surfaces where device patterns are formed) of substrates W.

Each of the cleaning units 61 includes a spin chuck 611 that absorbs and holds a substrate W in a horizontal position and rotates the substrate W; a cleaning brush 612 that scrubs and cleans the surface of a substrate W held on the spin chuck 611 in contact therewith or in proximity thereto; and a supply nozzle 613 that discharges a given cleaning liquid (e.g., pure water) onto a substrate W held on the spin chuck 611. The supply nozzle 613 is in connection with a cleaning-liquid supply system (not shown).

The cleaning units 61 with such a structure perform scrub cleaning on substrates W transported therein by the center robot 70 which will be described later. The scrub cleaning is performed, for example, in the following way. First, the spin chuck 611 absorbs and holds a substrate W, which is transported therein by the center robot 70, in a horizontal position on its upper surface and rotates the substrate W on a vertical axis passing through the center of the substrate W. Also, the supply nozzle 613 discharges and supplies a cleaning liquid toward the surface of the substrate W held on the spin chuck 611. In this condition, the cleaning brush 612 is brought in contact with or in proximity to the surface of the substrate W on the spin chuck 611 to remove particles or the like on the surface of the substrate W.

Each of the cleaning units 61 includes a cup (not shown) that surrounds the substrate W held on the spin chuck 611. The cleaning liquid dispersed from the substrate W during scrub cleaning is received by the inner side of this cup and led to a given drain line.

### [Center Robot 70]

The center robot 70 is a transporter that transports substrates W between the substrate transfer part 50 and the cleaning parts 60. To be more specific, the center robot 70 takes out a substrate W (unprocessed substrate) placed on a given PASS 51 of the substrate transfer part 50 and transports the substrate W into a given cleaning unit 61. Or, the center robot 70 takes out a substrate W (processed substrate) scrubbed and cleaned in a given cleaning unit 61 and transfers the substrate W to a given PASS 51.

The structure of the center robot 70 is now described in more detail. The center robot 70 is almost identical in structure to the indexer robot 40. Specifically, the center robot 70 includes two transport arms 71a and 71b, an arm stage 72 mounting the transport arms 71a and 71b, and a fixed stage 73 mounting the arm stage 72.

The fixed stage 73 is fixed to the base of the cleaning cell SP and includes a built-in motor that drives the arm stage 72 to pivot on an axis along the vertical (Z-axis) direction and another built-in motor that moves the arm stage 72 up and down in the vertical direction. The two transport arms 71a and 71b are spaced one above the other on the arm stage 72. Each of the transport arms 71a and 71b includes a frame 711 at the end portion and supports the edge of a substrate W from below, using a plurality of pins 712 that protrude inward from inside the frame 711. The arm stage 72 also includes a built-in slide drive mechanism that moves the transport arms 71a and 71b back and forth in the horizontal direction (in the radial direction of the pivot of the arm stage 72).

The center robot 70 with such a structure allows its transport arms 71a and 71b to move up and down, to pivot in a horizontal plane, and to move back and forth in the radial direction of the pivot. In other words, the center robot 70 pivots the transport arms 71a and 71b so that the transport arms 71a and 71b face a given cleaning unit 61, and further at that position, moves the transport arms 71a and 71b up and down and back and forth, thereby allowing the transport arms 71a and 71b to have access to a given cleaning unit 61. The center robot 70 also pivots the transport arms 71a and 71b so that the transport arms 71a and 71b face the substrate transfer part 50, and further at that position, moves the transport arms 71a and 71b up and down and back and forth, thereby allowing the transport arms 71a and 71b to have access to a given tier of PASSs 51.

The center robot 70, using either of the two transport arms 71a and 71b, takes out a substrate W (processed substrate) placed on the spin chuck 611 in a given cleaning unit 61, and it also places a substrate W (unprocessed substrate) held by the other of the arms on that spin chuck 611. Or, the center robot 70 moves to the substrate transfer part 50 while holding a substrate W (processed substrate) with one of the arms, and takes out a substrate W (unprocessed substrate) placed on a given PASS 51 with the other free arm and also places the holding substrate W held by the one arm on that PASS 51.

### <2. Processing Operation>

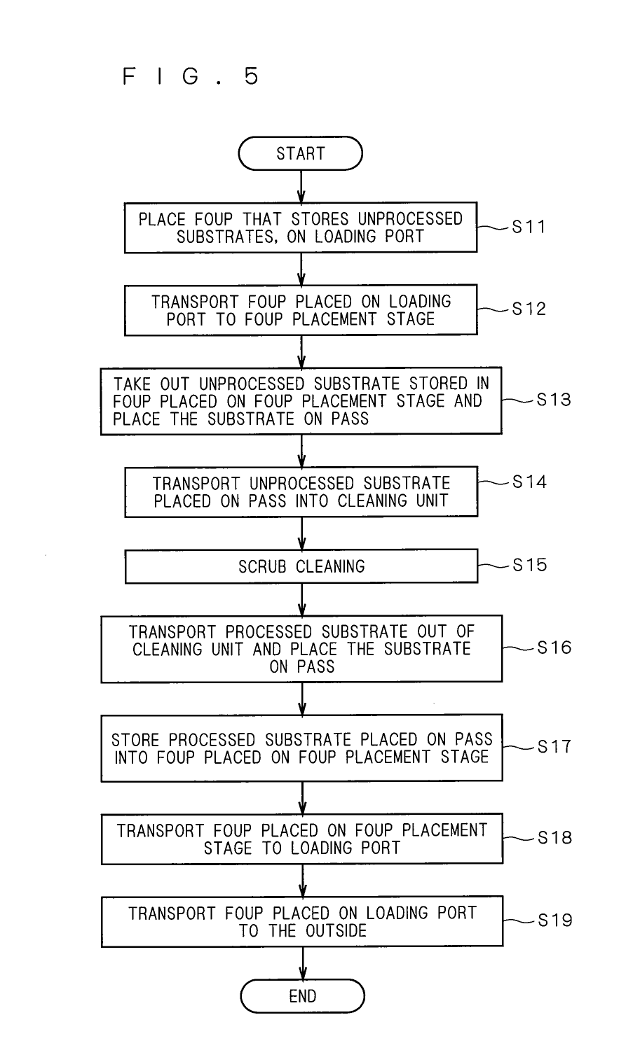

Next, the operation of the substrate processing apparatus 1 is described with reference to FIGS. 1 to 3 and the flow chart in FIG. 5. A series of processing operations described below shall be performed under control of the controller C that drives each functional unit.

When a vacancy occurs in a loading port 10, an external transporter (such as an OHT) transports and places an FOUP 80 that stores unprocessed substrates onto that free loading port 10 (step S11).

When a vacancy occurs in an FOUP placement stage 30, the FOUP transfer robot 20 transports and transfers an FOUP 80 (an FOUP that stores unprocessed substrates) placed on a loading port 10 to that free FOUP placement stage 30 (step S12).

When the FOUP 80 (the FOUP that stores unprocessed substrates) is stored on the FOUP placement stage 30, the opener 31 removes the front lid 83 of that FOUP 80. The indexer robot 40 then takes out an unprocessed substrate stored in the FOUP 80 in sequence and transfers it to a given PASS 51 in the substrate transfer part 50 (step S13).

The center robot 70 takes out a substrate W (unprocessed substrate) placed on the PASS 51 and transports it into a given cleaning unit 61 in a cleaning part 60 (step S14).

The cleaning unit 61 absorbs and holds the transported substrate W on the spin chuck 611 and performs scrub cleaning on the substrate W (step S15).

After completion of the scrub cleaning, the center robot 70 transports the scrubbed and cleaned substrate W out of the cleaning unit 61 and transfers it to the PASS 51 (step S16).

The indexer robot 40 takes out a substrate W (processed substrate) placed on a given PASS 51 and stores it into an FOUP 80 placed on a given FOUP placement stage 30 (step S17).

When the FOUP 80 placed on the FOUP placement stage 30 becomes full of processed substrates W, the opener 31 mounts and locks the front lid 83 of the FOUP 80. The FOUP transfer robot 20 then transports and transfers the FOUP 80 to a free loading port 10 (step S18).

When an FOUP 80 (an FOUP that stores processed substrates) is placed on a loading port 10, the external transporter transports the FOUP 80 out of the substrate processing apparatus 1.

### <3. Advantageous Effects>

In the substrate processing apparatus 1 according to the preferred embodiment described above, since the plurality of FOUP placement stages 30 around the indexer robot 40 each have an FOUP 80 placed thereon, the indexer robot 40 can access the FOUPs 80 and the substrate transfer part 50 without moving in the horizontal direction. This reduces the time required for substrate transport.

Also, since the substrate processing apparatus 1 according to the preferred embodiment described above includes the plurality of FOUP placement stages 30, the substrate transport operation of the indexer robot 40 is not interrupted. The reason is as follows. For example if each FOUP 80 shall store 13 substrates W, 13 unprocessed substrates stored in an FOUP 80 (a first FOUP 80) placed on a given FOUP placement stage 30 are processed in sequence in the cleaning units 61. In this case, at the time when the thirteenth substrate W stored in the first FOUP 80 is transported as an unprocessed substrate out to the substrate transfer part 50, for example the fourth substrate W shall return as a processed substrate from the substrate transfer part 50. Since there is no more unprocessed substrate W left in the first FOUP 80, if there were only a single FOUP placement stage 30, the indexer robot 40 would have to stop placing an unprocessed substrate in the substrate transfer part 50 during the time until the fifth to thirteenth substrates W had been processed and returned. That is, the transport of the substrates W would be interrupted. This also results in an intermission of cleaning in the cleaning units 61. On the other hand, if there are a plurality of FOUP placement stages 30, the indexer robot 40 can, during this while, transfer unprocessed substrates W, which are stored in an FOUP 80 (a second FOUP 80) placed on another FOUP placement stage 30, to the substrate transfer part 50. That is, the transport of the substrates W is not interrupted. This reduces the time required for substrate transport. Besides, no intermission of cleaning in the cleaning units 61 improves processing efficiency.

In the substrate processing apparatus 1 according to the preferred embodiment described above, each of the FOUP placement stages 30 and the substrate transfer part 50 are so located as to form an angle of 90 degrees as viewed from the indexer robot 40. The indexer robot 40 can thus, without any waste of time, perform the operation of transferring unprocessed substrates stored in FOUPs 80 placed on the FOUP placement stages 30 to the PASSs 51 and the operation of taking out processed substrates from the PASSs 51 and then storing those substrates to FOUPs 80. This reduces the time required for substrate transport.

In the substrate processing apparatus 1 according to the preferred embodiment described above, an FOUP 80 placed on a loading port 10 is once transported to an FOUP placement stage 30 by an external transporter, and then the indexer robot 40 transports a substrate W between the FOUP placement stage 30 and the substrate transfer part 50. Although the level of the loading ports 10 may sometimes be limited by the specifications of the external transporter or the like, such limitations are not applied to the level of the FOUP placement stages 30. It is thus possible, as in the preferred embodiment described above, to locate FOUPs 80 placed on the FOUP placement stages 30 and the substrate transfer part 50 at approximately the same level. This reduces the distance of substrate transport, thus reducing the time required for substrate transport.

Besides, locating the FOUP placement stages 30 and the substrate transfer part 50 at relatively high levels allows the indexer robot 40 to be located at a high level. This produces a space V under the indexer robot 40 as shown in FIG. 3, and this space V can effectively be used for example as a storage unit. For instance, a spraying unit or the controller C may be located in this space V.

In the preferred embodiment described above, the substrate transfer part 50 is provided with the three tiers of PASSs 51 stacked in layers. While transferring two unprocessed substrates to two of the PASSs 51, the center robot 70 takes out an unprocessed substrate placed on the other one of the PASSs 51. Since there are the three PASSs 51, two of the PASSs 51 are free in this condition, so that the indexer robot 40 can place unprocessed substrates on those two free PASSs 51. This improves transport efficiency.

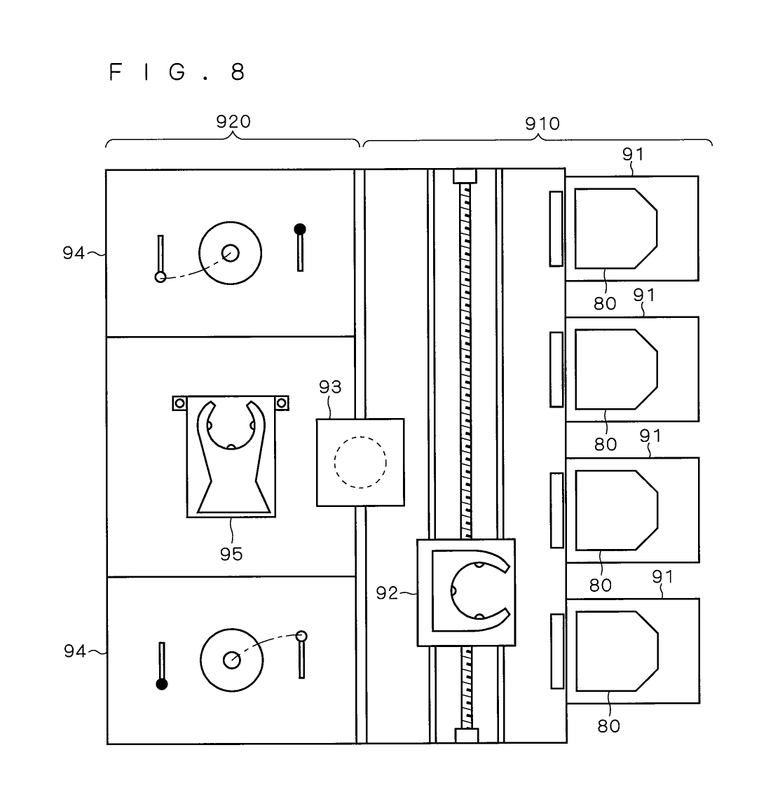

If, as in conventional cases, the transport robot 92 is configured to transport substrates W between the FOUPs 80 placed on the loading ports 91 and a substrate transfer part 93 (cf. FIG. 8), the FOUPs 80 now being processed occupy the loading ports 91. Thus, an external transporter cannot transport new FOUPs 80 into the substrate processing apparatus until a vacancy occurs in the loading ports 91. And, even when a vacancy occurs in the loading ports 91, it will take considerable time for the external transporter to transport new FOUPs 80 into the apparatus. Thus, if the external transporter has a low throughput and the substrate processing apparatus has a high throughput, the substrate processing apparatus may have to wait for the arrival of new FOUPs 80, which results in an interruption of processing. To avoid such a situation, it is contemplated to increase a total number of loading ports 91; however, increasing the number of loading ports 91 causes an increase in the distance traveled by the transport robot 92, thus reducing the throughput of the substrate processing apparatus.

In the preferred embodiment described above, on the other hand, the FOUPs 80 being processed do not occupy the loading ports 10. Thus, an external transporter can transport new FOUPs 80 one after another into the apparatus, which reduces the risk of putting the substrate processing apparatus 1 into a standby mode for waiting for FOUPs 80. In other words, the throughput of the substrate processing apparatus 1 is less likely to be affected by the throughput of the external transporter. For example, even if the external transporter has varying transport times, the substrate processing apparatus 1 is less likely to be affected thereby. Besides, the shortened time of occupancy of the loading ports 10 by the FOUPs 80 allows a reduction in a total number of loading ports 10. This can also result in a reduced footprint of the apparatus.

### <4. Other Preferred Embodiments>

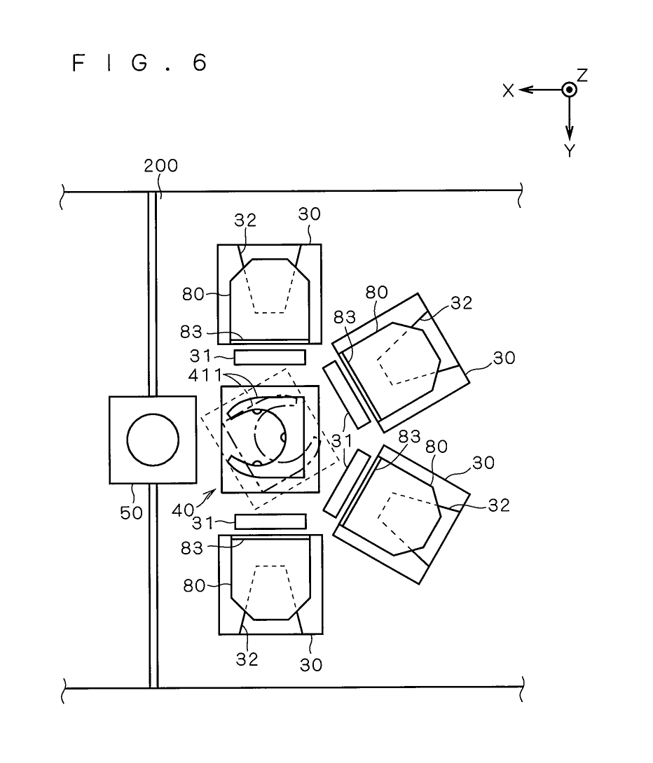

While the preferred embodiment described above provides the configuration with two FOUP placement stages 30, the number of FOUP placement stages 30 may be three or more. Also in such a case, each of the FOUP placement stages 30 should be located accessible from the indexer robot 40 without horizontal movement of the indexer robot 40. For example, as shown in FIG. 6, the FOUP placement stages 30 may be arranged radially relative to the indexer robot 40 (more specifically, on the circumference of a circle with center on a pivot extending in the vertical (Z-axis) direction of the arm stage 42). In such an arrangement, the transport arms 41a and 41b will have access to an FOUP 80 placed on a given FOUP placement stage 30 by pivoting the arm stage 42 in a horizontal plane and moving the transport arms 41a and 41b back and forth in the radial direction of the pivot of the arm stage 42.

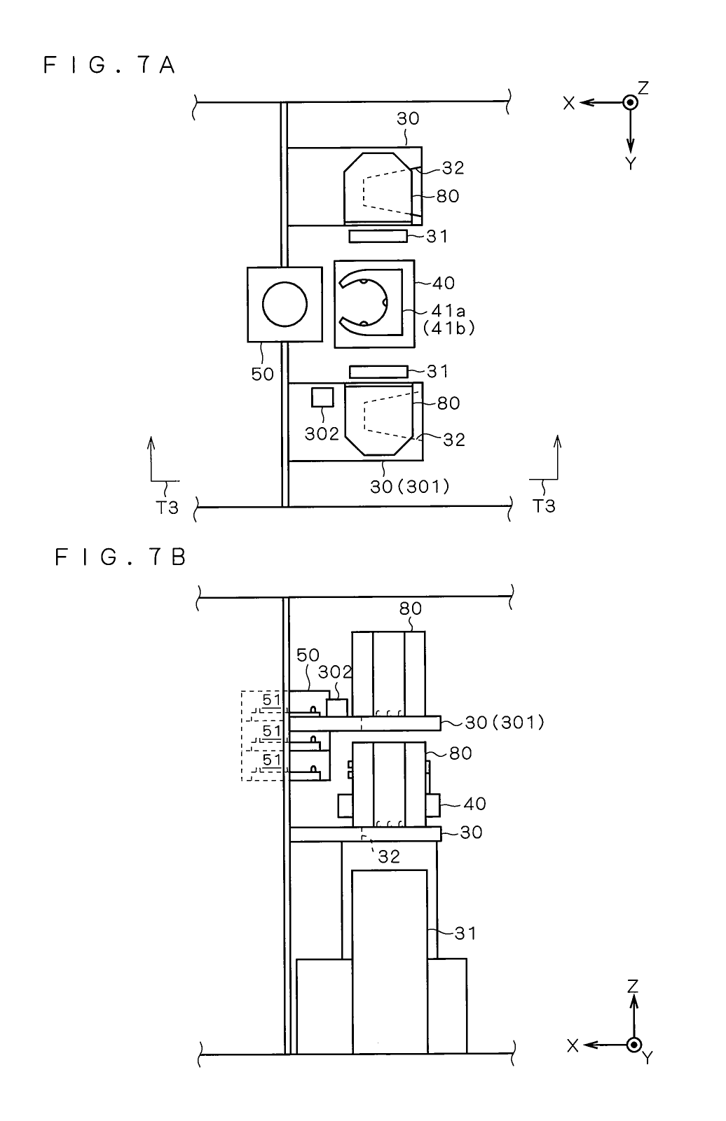

Further, as shown in FIGS. 7A and 7B, a plurality of FOUP placement stages 30 may be stacked one above another in layers. FIG. 7A is a plan view of a substrate processing apparatus according to this preferred embodiment, and FIG. 7B is a side sectional view of this substrate processing apparatus as viewed in the direction of the arrow T3. With the FOUP placement stages 30 arranged in this fashion, the transport arms 41a and 41b will have access to a given FOUP placement stage 30 by pivoting the arm stage 42 in a horizontal plane and further moving the arm stage 42 up and down, and then by moving the transport arms 41a and 41b back and forth in the radial direction of the pivot of the arm stage 42.

Alternatively, one of a plurality of FOUP placement stages 30 may be used for mapping. For example, as shown in FIGS. 7A and 7B, one of the plurality of FOUP placement stages 30 may be a mapping FOUP placement stage 301. In such a case, the mapping FOUP placement stage 301 is provided with a counter 302 that counts the number of substrates W stored in an FOUP 80 placed thereon. When the FOUP transfer robot 20 transfers an FOUP 80 to the mapping FOUP placement stage 301, the opener 31 first removes the front lid 83 of the FOUP 80 placed, and then the counter 302 counts the number of substrates W stored in that FOUP 80 to obtain mapping data. The obtained mapping data is sent to the controller C, which then controls each part based on the received mapping data.

While the indexer robot 40 in the preferred embodiments described above includes the two transport arms 41a and 41b, the number of transport arms is not necessarily two. For example, a transport robot with one arm or that with three arms may be employed as an indexer robot.

While the preferred embodiment described above provides the configuration in which two unprocessed substrates W are simultaneously taken out of an FOUP 80 using the two arms, it is not a necessity to simultaneously take out two substrates; substrates may be taken out one at a time.

While, in the preferred embodiment described above, the substrate transfer part 50 includes three tiers of PASSs 51 stacked in layers, the number of PASSs 51 is not necessarily three; it may, for example, be two, or four or more.

While the preferred embodiment described above provides the configuration in which the transfer of substrates W between both of the cells is made through the substrate transfer part 50, the way of transferring substrates W between both of the cells is not limited thereto. For instance, substrates W may be transferred directly between the indexer robot 40 and the center robot 70. In this case, the substrate transfer position should be on the transport arms 71a and 71b of the center robot 70. Specifically, the indexer robot 40 transfers a substrate W stored in an FOUP 80 placed on a given FOUP placement stage 30 to a given substrate transfer position (in the present example, one arm of the center robot 70), and stores a substrate W received from a given substrate transfer position (in the present example, the other arm of the center robot 70) in an FOUP 80 placed on a given FOUP placement stage 30.

While in the preferred embodiment described above, each of the two cleaning parts 60 includes four cleaning units 61 stacked in layers and each of the cleaning units 61 cleans the surface of a substrate W, the number of cleaning units 61 is not limited thereto; it may, for example, be three, or five or more.

While the preferred embodiment described above provides the configuration in which the eight cleaning units 61 are used to clean the surfaces of substrates W, all or some of the cleaning units 61 may be used as back-side cleaning units that clean the back sides of substrates W. Such back-side cleaning units, however, need to use a spin chuck in the form of mechanically holding the edge of a substrate W, instead of being in the form of absorbing and holding a substrate W. When the cleaning units 61 perform back-side cleaning, it is necessary to provide, at any place in the substrate processing apparatus 1, a reverse unit that reverses a substrate W upside down. The reverse unit may for example be provided in the substrate transfer part 50. If the substrate transfer part 50 is provided with such a reverse unit, the reverse unit may also serve as a substrate placement part. In this case, for example, three tiers of reverse units, each of which may also be used as a substrate placement part, should be stacked in layers. Or, if the reverse unit does not serve as a substrate placement part, the substrate transfer part 50 may be configured, for example by stacking each part in layers in the order of a reverse unit, a substrate placement part, a substrate placement part, and a reverse unit from top to bottom.

While in the preferred embodiment described above, the FOUP transfer robot 20 lifts an FOUP 80 from the underside during transport, a transport system may be so configured as to suspend an FOUP 80 during transport while holding the flange 82 formed on the top of the casing 81 from both sides with arms or the like.

While the invention has been shown and described in detail, the foregoing description is in all aspects illustrative and not restrictive. It is therefore understood that numerous modifications and variations can be devised without departing from the scope of the invention.

What is claimed is:

1. A single-wafer-processing-type substrate processing apparatus processing one substrate at a time, the substrate being stored in a holder storing a plurality of substrates,
said substrate processing apparatus comprising:
a plurality of first placement parts placing said holder for transfer of said holder to and from outside the apparatus;
a plurality of second placement parts arranged on the circumference of a circle with center on a given vertical axis;
a holder transporter transporting said holder placed on any one of said plurality of first placement parts to any one of said plurality of second placement parts; and
a substrate transfer part fixedly provided in such a position that a pivot extending vertically to said substrate transfer part agrees with said given vertical axis, said substrate transfer part, without moving in a horizontal direction, taking a substrate out of said holder placed on any one of said plurality of second placement parts to transfer the substrate to a given substrate transfer position or storing a substrate received from said substrate transfer position into said holder.

2. The substrate processing apparatus according to claim 1, wherein
each of said plurality of second placement parts and said substrate transfer position are so located as to form an angle of 90 degrees as viewed from said substrate transfer part.

3. The substrate processing apparatus according to claim 1, wherein
said plurality of second placement parts include two second placement parts.

4. The substrate processing apparatus according to claim 1, wherein
an average level at which an access is made to said holder placed on each of said plurality of second placement parts is approximately the same as an average level at which an access is made to said substrate transfer position.

5. The substrate processing apparatus according to claim 1, further comprising:
a cleaning part cleaning a substrate; and
a transporter transporting a substrate between said cleaning part and said substrate transfer position.

6. A substrate transport method for transporting a substrate in a substrate processing apparatus that includes a single-wafer-processing-type substrate processing unit that processes one substrate at a time,
said substrate transport method comprising the steps of:
a) receiving a holder that stores a plurality of unprocessed substrates from outside the apparatus and placing said holder on any one of a plurality of first placement parts;
b) transporting said holder placed on any one of said plurality of first placement parts to any one of a plurality of second placement parts that are arranged on the circumference of a circle with center on a given vertical axis; and
c) using a substrate transfer part fixedly provided in such a position that a pivot extending vertically to said substrate transfer part agrees with said given vertical axis, taking a substrate out of said holder placed on any one of said plurality of second placement parts to transfer the substrate to a substrate transfer position which is on the way to said substrate processing unit.

7. A substrate transport method for transporting a substrate in a substrate processing apparatus that includes a single-wafer-processing-type substrate processing unit that processes one substrate at a time,
said substrate transport method comprising the steps of:
a) using a substrate transfer part, storing a substrate received from a substrate transfer position, which is on the way to said substrate processing unit, into a holder that stores a plurality of processed substrates and that is placed on any one of a plurality of second placement parts arranged on the circumference of a circle with center on a pivot extending vertically to said substrate transfer part,
b) transporting said holder placed on any one of said plurality of second placement parts to any one of a plurality of first placement parts; and
c) transporting said holder placed on any one of said plurality of first placement parts, out of the apparatus.
